(19) United States
(12) Patent Application Publication
(10) Pub. No.: US 2008/0013019 A1
(43) Pub. Date: Jan. 17, 2008

(54) Color filter, process of producing the color filter, and liquid crystal display device employing the color filter

(75) Inventor: Susumu Sugiyama, Minami-ashigara-shi (JP)

Correspondence Address: BUCHANAN, INGERSOLL & ROONEY PC, POST OFFICE BOX 1404, ALEXANDRIA, VA, 22313-1404, US

(73) Assignee: FUJIFILM Corporation, Tokyo (JP)

(21) Appl. No.: 11/822,638

(22) Filed: Jul. 9, 2007

(30) Foreign Application Priority Data
Jul. 11, 2006 (JP) 2006/190039

(51) Int. Cl. G02F 1/1335; G03F 1/00

(52) U.S. Cl. 349/108; 430/4; 430/7

(57) ABSTRACT

A novel color filter to be employed in a liquid crystal display device is disclosed. The color filter comprises at least two colored sub-pixels in each pixel; at least one of the colored sub-pixels in each pixel comprises a retardation-controlling agent; and retardation is substantially different from each other between the two colored sub-pixels.

### CROSS-REFERENCE TO RELATED APPLICATIONS

This application claims benefit of priority under 35 U.S.C. 119 to Japanese Patent Application No. 2006-124821 filed Apr. 28, 2006, and the entire content of the application is incorporated herein by reference.

### BACKGROUND OF THE INVENTION

1. Field of the Invention

The present invention relates to a color filter, a process for producing a color filter and a liquid crystal display device. The present invention also relates to a transfer material which is useful in preparing a color filter and a process for producing it.

2. Related Art

A liquid crystal display device usually comprises a liquid crystal cell and two polarizing plates. A polarizing plate usually comprises two protective films and a polarizing film, and is produced typically by bonding protective films such as cellulose acylate films to both surfaces of a polarizing film, which is produced by dying a polyvinyl alcohol film with iodine and then stretching it. A transmissive liquid crystal display device usually has a polarizing plate on both sides of the liquid crystal cell respectively, and occasionally has one or more optical compensation films. A reflective liquid crystal display device usually comprises a reflector plate, the liquid crystal cell, one or more optical compensation films, and a polarizing plate in this order. The liquid crystal cell comprises liquid-crystalline molecules, two substrates encapsulating the liquid-crystalline molecules, and electrode layers capable of applying voltage to the liquid-crystalline molecules. The liquid crystal cell switches ON and OFF displays depending on variation in orientation state of the liquid-crystalline molecules, and is applicable both to transmission type and reflective type, of which display modes ever proposed include TN (twisted nematic), IPS (in-plane switching), OCB (optically compensatory bend), VA (vertically aligned) and ECB (electrically controlled birefringence).

Among these, a 90 degree-twisted nematic LCD, employing nematic liquid crystal molecules showing positive dielectric anisotropy and driven by a thin-film transistor (referred to as “TN mode”), has been mainly used in applications which require high displaying quality. Although a TN mode can provide an excellent displaying property in a normal direction, it provides a low displaying property such as a low contrast and gray scale inversion and an inversion of brightness in a gray scale in an oblique direction. And there is strong demand for improvement of such a viewing angle property.

On the other hand, wide-viewing angle liquid crystal modes such as IPS, OCB and VA modes gain more market share according with a recent increase in demand for liquid crystal TV. Although all of the modes provide higher and higher displaying qualities, color shift generating in an oblique direction haven't been overcome yet.

As a retardation plate, especially as a ¼ wavelength plate, a polymer orientation film satisfying 0.6<Δn·d(450)/Δn·d(550)<0.97, and 1.01<Δn·d(650)/Δn·d(550)<1.35, where Δn·d(λ) is retardation at a wavelength λ nm, is known (Japanese Laid-Open Patent Publication “Tokkai” No. 2000-137116).

As a means for widening a viewing angle of LCD, disposing a component capable of optical compensation inside of a liquid cell has been proposed.

In Japanese Laid-Open Patent Publication “Tokkai” No. 2002-122866, it is proposed to employ a color filter layers, red (R), green (G) and blue (B) layers, each of which is birefringent and can function as a retardation layer, for improving a viewing angle property and for reducing coloration in a gray state.

As a means for controlling retardation in each colored layer, there are proposed controlling a thickness to differ among R, G and B layers so that a liquid crystal layer can generate retardation equal to λ/2 (where λ is a wavelength) at all of R, G and B (Japanese Laid-Open Patent Publication “Tokkai” Nos. 2001-290149 and 2004-191832); forming retardation layers in the regions corresponding to R, G and B sub-pixels respectively by using a polymerizable liquid crystal material so that the thickness of each retardation layer is different among the retardation layers disposed in the regions corresponding to R, G, and B sub-pixels respectively (Japanese Laid-Open Patent Publication “Tokkai” No. 2002-14333); and forming retardation layers in the regions corresponding to R, G and B sub-pixels respectively by irradiating a polymerizable liquid crystal material with UV light at a temperature which is different among when forming the retardation layers in the regions corresponding to R, G and B sub-pixels (Japanese Laid-Open Patent Publication “Tokkai” No. 2004-205801).

All of the supposed methods require complicated treatments for forming the color filter layer on a substrate for varying retardation among R, G and B layers. In particular, they require steps to be controlled strictly for forming each colored layer, for example, forming each colored layer by applying a photoresist fluid to a surface in a different direction with a different shearing force or forming each colored layer by curing a polymerizable liquid crystal at a different temperature; and, therefore, it is difficult to raise its production ratio or production yield ratio to a practical level. The problem for a practical use also resides in varying the thickness among the R, G, and B layers because the design of pixels and driving method is restricted for avoiding disorder of orientation generated due to a thickness-gap in boundaries between the colored layers.

### SUMMARY OF THE INVENTION

One object of the invention is to provide a color filter to be employed in a LCD contributing to improvement in contrast and coloration in an oblique direction in a black state with a good production ratio and a good production yield ratio according to an easily-controllable method.

Another object of the invention is to provide a color filter contributing to optical compensation.

Another object of the invention is to provide a liquid crystal display device improved in contrast and coloration in an oblique direction in a black state.

Another object of the invention is to provide a transfer material useful for producing color filters and a process for producing a transfer material stably.

In one aspect, the invention provides a color filter to be employed in a liquid crystal display device, comprising at least two colored sub-pixels in each pixel,

wherein at least one of the colored sub-pixels in each pixel comprises a retardation-controlling agent, and retardation is substantially different from each other between the two colored sub-pixels.

As an embodiment of the invention, the color filter wherein at least one sub-pixel comprises a plurality of domains among which retardation is substantially different from each other is provided.

In another aspect, the invention provides a liquid crystal display device comprising a color filter; the liquid crystal display, comprising a retardation plate disposed outside of a liquid crystal cell; a photosensitive transfer material comprising a photosensitive polymer layer comprising at least one retardation-controlling agent; a process for producing a photosensitive transfer material comprising applying a photosensitive polymer composition comprising at least one retardation-controlling agent to a surface to form a photosensitive polymer layer; a process for producing a color filter to be employed in a liquid crystal display device comprising forming a photosensitive polymer layer comprising at least one retardation-controlling agent on a surface of a substrate; a process for producing a color filter to be employed in a liquid crystal display device comprising forming a photosensitive polymer layer comprising at least one retardation-controlling agent on a surface of a substrate, exposing the layer at least one time, developing the layer at least one time, and baking the layer at least one time.

### BRIEF DESCRIPTION OF THE DRAWINGS

FIG. 1 is an oblique perspective figure of an example of a pixel in a color filter of one embodiment of the invention.

FIG. 2 is an oblique perspective figure of an example of a pixel in a color filter of another embodiment of the invention.

### DETAILED DESCRIPTION OF THE INVENTION

The present invention will be described in detail.

It is to be noted, in this description, that the term “ . . . to . . . ” is used as meaning a range inclusive of the lower and upper values disposed therebefore and thereafter.

In this specification, Re(λ) and Rth(λ) represent in-plane retardation and in-thickness direction retardation at wavelength λ, respectively. Re(λ) is measured using KOBRA 21ADH or WR (from Oji Scientific Instruments), by irradiating the film with a λ-nm light in the direction of normal line of the film.

Regarding a film expressed by a monoaxial or biaxial index ellipsoid, Rth(λ) can be calculated by the method as described below.

Rth(λ) is calculated by KOBRA 21ADH or WR is calculated based on six Re(λ) values which are measured for incoming light of a wavelength λ nm in six directions which are decided by a 10° step rotation from 0° to 50° with respect to the normal direction of a sample film using an in-plane slow axis, which is decided by KOBRA 21ADH, as an a tilt axis (a rotation axis; defined in an arbitrary in-plane direction if the film has no slow axis in plane); a value of hypothetical mean refractive index; and a value entered as a thickness value of the film.

When a sample film gives no retardation, zero, for incoming light in the direction rotated at a certain angle with respect to the normal direction of the film using an in-plane slow axis as a rotation axis, any retardation values obtained at angles larger than that angle will be calculated by KOBRA 21ADH or WR, after being inverted in the sign to minus.

It is to be noted that Rth can be also calculated from equations (1) and (2) below, based on two retardation values measured for incoming light in two rotated directions, while assuming the slow axis as a tilt axis (a rotation axis: defined in an arbitrary in-plane direction if the film has no slow axis); a hypothetical value of the mean refractive index, and an entered value of the thickness.

$$\begin{matrix}Re ( θ ) = [ nx - \frac{ny \times nz}{\sqrt{\begin{matrix}{\{ ny sin ( {sin}^{- 1} ( \frac{sin ( - θ )}{nx} ) ) \}}^{2} + \\ {\{ nz cos ( {sin}^{- 1} ( \frac{sin ( - θ )}{nx} ) ) \}}^{2}\end{matrix}}} ] \times \frac{d}{cos \{ {sin}^{- 1} ( \frac{sin ( - θ )}{nx} ) \}} & Equation ( 1 ) \\ Rth = \{ ( nx + ny ) / 2 - nz \} \times d & Equation ( 2 )\end{matrix}$$

### Notes:

In the equation, Re(θ) represents retardation value in the direction rotated by angle θ from the direction of normal line.

In the equations, nx represents in-plane refractive index in the direction of slow axis; ny represents in-plane refractive index in the direction normal to nx; nz represents refractive index in the direction normal to nx and ny; and d (nm) is a thickness of the film.

For any films which cannot be expressed by a monoaxial or biaxial index ellipsoid, that is so-called, optic-axis-free film, Rth(λ) is calculated by the procedures below.

The Re(λ) is measured by using KOBRA-21ADH (manufactured by Oji Scientific Instruments) for an incoming light of a wavelength λ nm in a vertical direction to a film-surface. The Rth(λ) is calculated by using KOBRA-21ADH based on plural retardation values which are measured for incoming light of a wavelength λ nm in eleven directions which are decided by a 10° step rotation from −50° to +50° with respect to the vertical direction of the film using an in-plane slow axis, which is decided by KOBRA 21ADH, as an a tilt axis (a rotation axis); value of hypothetical mean refractive index; and a value entered as a thickness value of the film.

In the above-described measurement, the hypothetical value of mean refractive index is available from values listed in catalogues of various optical films in Polymer Handbook (John Wiley & Sons, Inc.). Those having the mean refractive indices unknown can be measured using an Abbe refract meter. Mean refractive indices of some major optical films are listed below:

cellulose acylate (1.48), cycloolefin polymer (1.52), polycarbonate (1.59), polymethylmethacrylate (1.49) and polystyrene (1.59).

KOBRA 21ADH or WR calculates nx, ny and nz, upon enter of the hypothetical values of these mean refractive indices and the film thickness. Base on thus-calculated nx, ny and nz, Nz=(nx−nz)/(nx−ny) is further calculated.

In the specification, the condition “retardation is substantially different from each other between two colored sub-pixels in each pixel” requires that either Re or Rth or Both of Re and Rth are different from each other by 2 nm or more between two colored sub-pixels. The condition “retardation is substantially different from each other between two colored domains in each sub-pixel” requires that either Re or Rth or Both of Re and Rth are different from each other by 2 nm or more between two colored domains. In any embodiments of the invention, the retardation value of each colored sub-pixel or each domain is measured at a wavelength of 446 nm, 548 nm or 629 nm; and the wavelength is selected for each sub-pixel or each domain so that light at the wavelength passes through the colored sub-pixel or the domain with the highest transmittance among light at these wavelengths.

The invention relates to a color filter to be employed in a liquid crystal display device, comprising at least two colored sub-pixels in each pixel,

wherein at least one of the colored sub-pixels in each pixel comprises a retardation-controlling agent, and retardation is substantially different from each other between the two colored sub-pixels in each pixel.

The inventors conducted various studies, and as a result, they found that, by adding a retardation controlling agent to a color filter layer so as that sub-pixels of a color thereof has different retardation from that of sub-pixels of another color, it is possible to achieve a viewing-angle compensation of a liquid crystal cell at almost all of visible light range in the black state without employing polymerized liquid crystal layer other than the color filter or without changing the thickness among the sub-pixels respectively having a color different from each other.

According to the invention, it is possible to provide each colored sub-pixel with a retardation value which is different from that of another colored sub-pixel by adding or not adding a retardation control agent to each colored sub-pixel, or deciding the amount or the type of the agent for each colored sub-pixel. The retardation value for each colored sub-pixel is not to be limited to any range, and may be decided depending on the color of the sub-pixel.

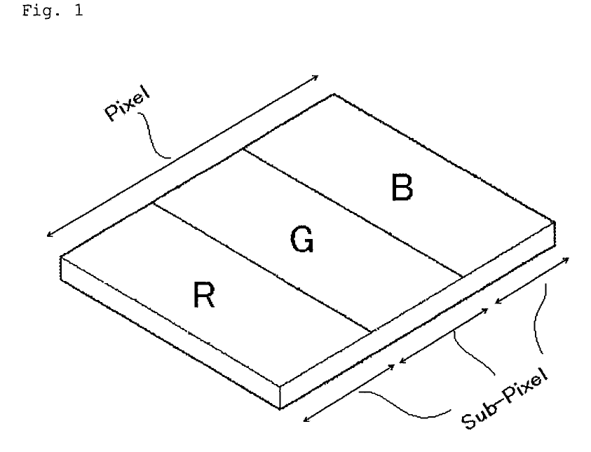

One embodiment of the color filter of the invention is a color filter comprising RGB, three primary colored, pixels. FIG. 1 is an oblique perspective figure of an example of a pixel in the color filter of this embodiment. In this embodiment, as shown in FIG. 1, each pixel consisting R, G and B colored layers, or, in other words, R, G and B colored sub-pixels. At least one of R, G and B colored layers (sub-pixels) in each pixel comprises a retardation controlling agent; and the retardation values of them are decreased in the order of the R layer, the G layer and the B layer. For controlling the retardation values to the optimum ranges, all of the R, G and B layers may comprise a retardation controlling agent, and in such an embodiment, the retardation controlling agent employed in each colored layer may be same or different each other. Employing a same agent for controlling the retardation values of two or more colored layers, the retardation value of each colored layer may be adjusted within the preferred range by controlling the amount of the agent.

The present invention also relates to the color filter wherein at least one sub-pixel comprises a plurality of domains among which retardation is substantially different from each other, and to a liquid crystal display device comprising the same. This embodiment is especially effective as a color filter comprising sub-pixels, each of which is divided into one or more domains corresponding tilt directions, inclination directions or rotating directions of liquid crystal molecules in a cell.

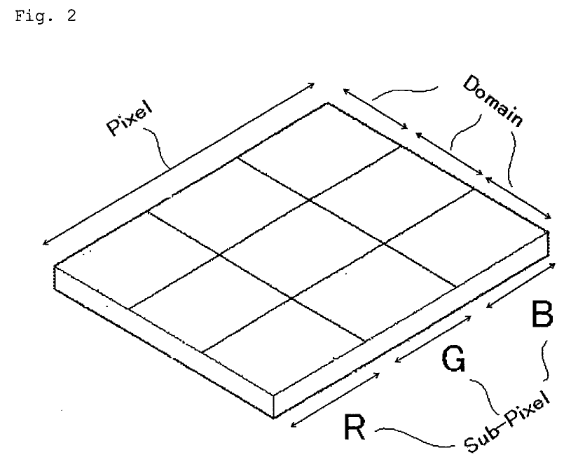

FIG. 2 is an oblique perspective figure of an example of a pixel in the color filter of this embodiment. In this embodiment, as shown in FIG. 2, each sub-pixel of the color filter is divided into multi domains corresponding to the domains of a liquid crystal cell; and the retardation of each domain is different among the domains in each sub-pixel. There have been provided liquid crystal cells with multi domains in each sub-pixel, which are divided so that tilt directions, inclining directions and rotating directions of liquid crystal molecules in a liquid crystal layer are averaged. This embodiment is especially effective for such multi domains liquid crystal cell.

By employing such a color filter, it is possible to achieve a viewing-angle compensation of a liquid crystal cell at almost all angles (polar angles and azimuth angles) in the black state.

According to the invention, it is possible to provide each domain with a retardation value different from another domain by adding or not adding a retardation control agent to each domain, or deciding the amount or the type of the agent for each domain.

### [Retardation Controlling Agent]

In the color filter of the invention, a color filter layer of at least one colored sub-pixel comprises a retardation controlling agent.

In the specification, the term “retardation controlling agent” is used for any agents capable of increasing retardation and any agents capable of decreasing agents when they are added. As described above, the term “retardation” is used for either Re or Rth and for both of Re and Rth. The term “retardation controlling agent” means a agent capable of altering (increasing or decreasing) retardation by 2 nm or more than 2 nm. It is to be noted that a retardation controlling agent may generate various amounts of change in retardation depending on the rate of the agent to be added, the thickness of a layer to be formed or the like. Therefore, the above mentioned amount of change in retardation means an amount of change in retardation generated in a same usage pattern (e.g. same rate and same thickness of a layer).

In the invention, among retardation controlling agents, agents of capable of increasing retardation are employed preferably.

### (Re Controlling Agent)

In the invention, the compounds of which UV absorption spectra in solution show a maximum absorption at a wavelength (λmax) equal to or shorter than 250 nm are employed preferably as a retardation controlling agent, referred to as “Re controlling agent”, capable of controlling an absolute value of Re. Employing such a compound, it is possible to control an absolute value of retardation without changing the wavelength-dependency of Re in the visible wavelength range.

Preferred examples of the Re controlling agent include rod-like compounds; among these, rod-like compounds having at least one aromatic ring are more preferred; and rod-like compounds having two or more aromatic rings are much more preferred.

Among rod-like compounds, rod-like compounds having a linear molecular structure are preferred. The term “a compound having a linear molecular structure” means that a molecular structure of the compound is linear in the most stable thermodynamic state. The most stable thermodynamic state can be obtained by a crystal structure analysis or a molecular orbital calculation. For example, a molecular structure, which gives the smallest heat of formation, can be obtained by carrying out a molecular orbital calculation with a molecular orbital calculation software such as “WinMOPAC2000” provided by FUJITSU. The term “a linear molecular structure” means that a molecular structure angle is equal to or more than 140 degree. The rod-like compounds which can be used as an Re controlling agent are preferably selected from compounds showing liquid crystallinity, more preferably selected from compounds showing liquid crystallinity under heating, or, in other words, thermotropic liquid crystallinity. The rod-like compound may show a phase transition to a liquid crystal phase such as a nematic or smectic liquid crystal phase.

Examples of the rod-like compound, which can be used as an Re controlling agent, include compounds represented by the formula (1), preferably by the formula (2), described in Japanese Patent Laid-Open Publication “Tokkai” No. 2006-96876. And preferred examples of the rod-like compound include, but are not limited to, Compound Nos. (1) to (40) described in “Tokkai” No. 2006-96876, p. 10-14. And the entire contents of Japanese Patent Application No. 2004-284889 (“Tokkai” No. 2006-96876), especially the contents in the columns to [0040], are incorporated herein by reference.

The compound of which UV absorption spectra in solution show a maximum absorption at a wavelength (λmax) equal to or shorter than 250 nm can be employed in any combination with another compound in the invention.

The rod-like compound can be synthesized by referring to methods described in various literatures such as Mol. Cryst. Liq. Cryst., vol. 53, p. 229 (1979), Id. vol. 89, p. 93(1982), Id. vol. 145, p. 111 (1987), Id. vol. 170, p. 43 (1989), J. Am. Chem. Soc., vol. 113, p. 1349 (1991), Id. vol. 118, p. 5346 (1996), Id. vol. 92, p. 1582 (1970), J. Org. Chem., vol. 40, p. 420 (1975), Tetrahedron, vol. 48, 16 issue, p. 3437 (1992).

The amount of the Re controlling agent preferably ranges from 0.1 to 30 mass %, and more preferably from 0.5 to 20 mass % with respect to the total mass of the composition to be used for preparing each colored layer.

### (Rth Controlling Agent)

In the invention, the compounds of which UV absorption spectra in solution show a maximum absorption at a wavelength (λmax) ranging from 250 to 400 nm are employed preferably as a retardation controlling agent, referred to as “Rth controlling agent”, capable of controlling an absolute value of Rth; and the compounds showing no absorption substantially at the visible wavelength range. The Rth controlling agent is preferably selected from the agents having no effect on the Re controlling agent to be used therewith.

The Rth controlling agent is preferably selected from discotic compounds.

Examples of the discotic compound include the compounds having at least one aromatic hydrocarbon ring or aromatic hetero ring. Among these, the compounds having a six-membered ring such as a benzene ring are more preferred.

In usual, an aromatic hetero ring is an unsaturated hetero ring. The aromatic hetero ring is preferably selected from 5-, 6- and 7-membered rings, and more preferably from 5- and 6-membered rings. In usual, an aromatic hetero ring is a hetero ring in which the maximum number of double bonds are embedded. Examples of the hetero atom include a nitrogen atom, oxygen atom and sulfur atom; and among these, a nitrogen atom is preferred. Examples of the aromatic hetero ring include a furan ring, thiophene ring, pyrrole ring, oxazole ring, isoxazole ring, thiazole ring, isothiazole ring, imidazole ring, pyrazole ring, furazane ring, triazole ring, pyrane ring, pyridine ring, pyridazine ring, pyrimidine ring, pyrazine ring and 1,3,5-triazine ring.

Among these, benzene ring, furan ring, thiophene ring, pyrrole ring, oxazole ring, thiazole ring, imidazole ring, triazole ring, pyridine ring, pyrimidine ring, pyrazine ring and 1,3,5-triazine ring are preferred; and 1,3,5-triazine ring is especially preferred. In particular, preferred examples of the triazine compound include the compound represented by the formula (I), (II), (III) or (IV) described in Japanese Patent Laid-Open Publication “Tokkai” No. 2003-344655. More specifically, preferred examples of the triazine compound include, but are not limited to, Compound Nos. I-(1) to I-(50), II-(1) to II-(9), III-(1) to III-(12) and IV-(1) to IV-(10) described in Tokkai No. 2003-344655, p. 9-18. And the entire contents of Japanese Patent Application No. 2002-149452 (“Tokkai” No. 2003-344655), especially contents in the columns of [0023] to [0056], are incorporated herein by reference.

The amount of the Rth controlling agent preferably ranges from 0.01 to 20 mass %, more preferably from 0.05 to 15 mass %, and much more preferably from 0.1 to 10 mass % with respect to the total mass of the composition to be used for preparing each colored layer. Two or more types of compound may be used as an Rth controlling agent.

The color filter of the invention may be prepared according to any general method such as a printing method, ink-jet method and transferring method. Among these, according to a transferring method employing a photosensitive transfer material, it is possible to prepare it stably.

It is preferred that the color filter of the invention is produced by using a photosensitive transfer material comprising a photosensitive polymer layer containing at least one retardation controlling agent. Such a photosensitive transfer material may be produced by applying a photosensitive polymer composition, containing at least one retardation controlling agent, into a band-shape to a surface to form a photosensitive polymer layer. And a long photosensitive transfer material may be produced continuously by applying the composition into a band-shape to a surface of a transported long temporary support such as a polymer film to form a photosensitive polymer layer continuously. According to the invention, it is preferred that the photosensitive polymer composition is extruded through a slit nozzle or the like so that molecules of the retardation controlling agent in the composition are aligned by the sharing force given during the extrusion. In particular, the photosensitive polymer composition, containing at least one retardation controlling agent, is applied through a slit nozzle in a band-shape to a surface of a transported temporary support such as a polymer film and dried on the surface under the condition selected appropriately in terms of the liquid viscosity of the composition at the time of outflow through the nozzle, the flow velocity of the composition, the slit width and the transport velocity of the temporary support, so that molecules of the retardation controlling agent in the composition can be aligned along with the transport direction or the direction perpendicular to the transport direction, and the desired retardation can be generated. The drying temperature and drying rate can also contribute to adjusting retardation within the desired range. Further, after drying to form the photosensitive polymer layer, stretching may be subjected to the photosensitive polymer layer to obtain the desired retardation.

The color filter is produced by using the photosensitive transfer material comprising the photosensitive polymer layer prepared according to the method described above. For example, the photosensitive transfer material and a substrate for supporting a color filter (in general, a glass substrate or the like to be employed in a liquid crystal cell) are laminated so that the slow axis of the layer is set at an appropriate position; and the photosensitive polymer layer is bonded to the surface of the substrate by a laminator to transfer from on the temporary support onto the substrate. After that, the photosensitive polymer layer, which is formed on the substrate by the transferring, may be subjected to a light exposure, development and baking treatments to form sub-pixels and/or domains of a same color. By repeating these steps, the color filter comprising sub-pixels and/or domains, wherein the sub-pixels and/or domains of each color have the desired retardation value, can be produced. By employing the photosensitive transfer material, it is possible to give an optimum retardation to the sub-pixels and/or domains of each color without any complicated treatments and any strict operations.

Further, the color filter produced by employing the photosensitive transfer material is excellent in terms of production rate or production yield ration since it is produced according to the simple and easily controlled method. Disorder may be hardly generated in the alignment due to the thickness gap; and, therefore, the pixel design or the driving method may be free from any restrictions.

Next, the photosensitive polymer composition which can be used in the invention will be described in detail; and, after that, the photosensitive polymer layer produced by using it, the photosensitive transfer material comprising the layer, and the method employing the material for producing a color filter will be described in detail.

### [Photosensitive Polymer Composition]

The photosensitive polymer composition, which can be used in the invention, comprises at least one retardation controlling agent; and is used for producing the photosensitive polymer layer which is one component of the photosensitive transfer material of the invention. After being transferred onto a substrate of a liquid crystal cell, the photosensitive polymer layer is subjected to various treatments such as a light exposure treatment and a development treatment to form a part (sub-pixels of a same color or domains of a same color in each sub-pixel) of a color filter. Accordingly, the photosensitive polymer layer may be produced by using a photosensitive polymer composition colored as same as the color of the target sub-pixels or domains. One example of the colored photosensitive polymer composition comprises the retardation controlling agent described above, (1) alkali-soluble binder, (2) monomer or oligomer, (3) photo-polymerization initiator or system, and (4) colorant.

The ingredients (1) to (4) will be described in detail.

### (1) Alkali-Soluble Binder

The alkali-soluble binder (which may be referred simply to as “binder”, hereinafter) is preferably selected from polymers having, in the side chain thereof, a polar group such as carboxylic acid groups or carboxylic salt. Examples thereof include methacrylic acid copolymer, acrylic acidcopolymer, itaconic acid copolymer, crotonic acid copolymer, maleic acid copolymer, and partially-esterified maleic acid copolymer described in Japanese Laid-Open Patent Publication “Tokkaisho” No. 59-44615, Examined Japanese Patent Publication “Tokkosho” Nos. 54-34327, 58-12577 and 54-25957, Japanese Laid-Open Patent Publication “Tokkaisho” Nos. 59-53836 and 59-71048. Cellulose derivatives having on the side chain thereof a carboxylic acid group can also be exemplified. Besides these, also cyclic acid anhydride adducts of hydroxyl-group-containing polymer are preferably used. Particularly preferable examples include copolymer of benzyl (meth)acrylate and (meth) acrylic acid described in U.S. Pat. No. 4,139,391, and multi-system copolymer of benzyl (meth)acrylate and (meth)acrylic acid and other monomer. These binder polymers having polar groups may be used independently or in a form of composition comprising a general film-forming polymer.

### (2) Monomer or Oligomer

According to the invention, the monomer or oligomer is preferably selected from compounds, having two or more ethylenic unsaturated double bonds, capable of causing addition polymerization induced by light irradiation. As such monomer and oligomer, compounds having at least one ethylenic unsaturated group capable of addition polymerization, and having a boiling point of 100° C. or above under normal pressure can be exemplified. Their examples include monofunctional acrylates and monofunctional methacrylates such as polyethylene glycol mono(meth)acrylate, polypropylene glycol mono(meth)acrylate and phenoxyethyl (meth)acrylate; multi-functional acrylates and multi-functional methacrylates, obtained by adding ethylene oxide or propylene oxide to multi-functional alcohols such as trimethylol propane and glycerin, and then converting them into (meth)acrylates, such as polyethylene glycol di(meth)acrylate, polypropylene glycol di(meth)acrylate, trimethylolethane triacrylate, trimethylolpropane tri(meth)acrylate, trimethylolpropane diacrylate, neopentyl glycol di(meth)acrylate, pentaerythritol tetra(meth)acrylate, pentaerythritol tri(meth)acrylate, dipentaerythritol hexa(meth)acrylate, dipentaerythritol penta(meth)acrylate, hexanediol di(meth)acrylate, trimethylol propane tri(acryloyloxypropyl)ether, tri(acryloyloxyethyl)isocyanurate, tri(acryloyloxyethyl) cyanurate, glycerin tri(meth)acrylate.

Additional examples of multi-functional acrylates and methacrylates include urethane acrylates such as those described in Examined Japanese Patent Publication “Tokkosho” Nos. 48-41708, 50-6034 and Japanese Laid-Open Patent Publication “Tokkaisho” No. 51-37193; polyester acrylates such as those described in Japanese Laid-Open Patent Publication “Tokkaisho” No. 48-64183, Examined Japanese Patent Publication “Tokkosho” Nos. 49-43191 and 52-30490; and epoxyacrylates which are reaction products of epoxy polymer and (meth)acrylic acid. Of these, trimethylolpropane tri(meth)acrylate, pentaerythritol tetra(meth)acrylate, dipentaerythritol hexa(meth)acrylate, dipentaerythritol penta(meth)acrylate are preferable.

Among these, trimethylolpropane tri(meth)acrylate, pentaerythritol tetra(meth)acrylate, dipentaerythritol hexa(meth)acrylate, and dipentaerythritol penta (meth)acrylate are preferred.

Besides these, also “polymerizable compound B” described in the Japanese Laid-Open Patent Publication “Tokkaihei” No. 11-133600 are exemplified as the preferable examples.

These monomers or oligomers can be used independently or in combination of two or more species thereof. The content of the monomer or oligomer generally falls in the range from 5 to 50% by mass, more preferably from 10 to 40% by mass, and much more preferably from 50 to 70% by mass, of the total mass of the solid components contained in the polymer composition. It is noted that the ratio of the monomer or oligomer to the binder preferably ranges from 0.5 to 1.2, more preferably 0.55 to 1.1 and much more preferably from 0.6 to 1.0.

### (3) Photopolymerization Initiator or Photopolymerization Initiator System

The photopolymerization initiator or photopolymerization initiator system used for the photosensitive polymer layer can be exemplified by vicinal polyketaldonyl compounds disclosed in U.S. Pat. No. 2,367,660, acyloin ether compounds described in U.S. Pat. No. 2,448,828, aromatic acyloin compounds substituted by α-hydrocarbon described in U.S. Pat. No. 2,722,512, polynuclear quinone compounds described in U.S. Pat. Nos. 3,046,127 and 2951758, combination of triaryl imidazole dimer and p-aminoketone described in U.S. Pat. No. 3,549,367, benzothiazole compounds and trihalomethyl-s-triazine compounds described in Examined Japanese Patent Publication “Tokkosho” No. 51-48516, trihalomethyl-triazine compounds described in U.S. Pat. No. 4,239,850, and trihalomethyl oxadiazole compounds described in U.S. Pat. No. 4,212,976. Trihalomethyl-s-triazine, trihalomethyl oxadiazole and triaryl imidazole dimer are particularly preferable.

Besides these, “polymerization initiator C” described in Japanese Laid-Open Patent Publication “Tokkaihei” No. 11-133600 can also be exemplified as a preferable example.

Such photopolymerization initiator or photopolymerization initiator system may be used independently or in a form of mixture of two or more species, wherein it is particularly preferable to use two or more species. Use of at least two species of photopolymerization initiator makes it possible to improve the display characteristics, and in particular to reduce non-uniformity in the display.

The content of the photopolymerization initiator or the photopolymerization initiator system preferably ranges from 0.5 to 20% by mass, and more preferably from 1 to 15% by mass, of the total mass of the solid components contained in the colored photosensitive polymer composition.

Among those exemplified above, any combinations of diazole series photo-polymerization initiators and triazine series photo-polymerization initiators are exemplified as an example exemplified preferably in terms of high sensitivity, no-coloration such as yellowing and good displaying properties; and, among such combinations, the combination of 2-trichloromethyl-5-(p-styryl styryl)-1,3,4-oxadiazole and 2,4-bis(trichloromethyl)-6-[4-(N,N-diethoxycarbonylmethyl)-3-bro mophenyl]-s-triazine is most preferred. The mass ratio of diazole series to triazine series in the combination preferably ranges from 95/5 to 20/80, more preferably from 90/10 to 30/70, and much more preferably from 80/20 to 60/40.

Examples of the photo-polymerization initiator, which can be used in the invention, include those described in Japanese Laid-Open Patent Publication “Tokkaihei” Nos. 1-152449, 1-254918 and 2-153353.

In the example comprising a pigment in an amount ranging from 15 to 25 mass % with respect to the total mass of the solid mass of the composition, coumarin series compound is preferably added to the photo-polymerization initiator system in terms of obtaining the same effect described above. As the coumarin compound, 7-[2-[4-(3-hydroxymethyl pyperidino)-6-diethylamino]triazinyl amino]-3-phenyl coumarin is most preferred.

The mass ratio of the photo-polymerization initiator system to the coumarin compound preferably ranges from 20/80 to 80/20, more preferably from 30/70 to 70/30, and much more preferably from 40/60 to 60/40.

### (4) Colorant

Examples of the colorant preferably used in the present invention include (i) C.I.Pigment Red 254 for the colored polymer composition for R(red), (ii) a mixture of C.I.Pigment Green 36 and C.I. pigment yellow (C.I.P.Y.) 139 for the colored polymer composition for G(green), and (iii) C.I.Pigment Blue 15:6 for the colored polymer composition for B(blue).

The content of C.I.P.R. 254 in the (i) R colored photosentitive polymer composition preferably ranges from 0.300 to 0.367 g/m², more preferably from 0.307 to 0.360 g/m² and much more preferably from 0.317 to 0.350 g/m² when the composition is applied to a surface so that the thickness of the dried layer is about 1 to 3 μm.

The content of C.I.P.G. 36 in the (ii) G colored photosensitive polymer composition preferably ranges from 0.438 to 0.535 g/m², more preferably from 0.448 to 0.525 g/m² and much more preferably from 0.462 to 0.511 g/m² when the composition is applied to a surface so that the thickness of the dried layer is about 1 to 3 μm.

The content of C.I.P.Y. 139 in the (ii) G colored photosensitive polymer composition preferably ranges from 0.072 to 0.088 g/m², more preferably from 0.074 to 0.086 g/m² and much more preferably from 0.076 to 0.084 g/m² in the same condition. the ratio of C.I.P.G. 36 to C.I.P.Y. 139 in the (ii) composition preferably ranges from 5.4 to 6.7, more preferably from 5.6 to 6.6, and much more preferably from 5.8 to 6.4.

The content of C.I.P.B. 15:6 in the (iii) B colored photosensitive polymer composition preferably ranges from 0.297 to 0.364 g/m², more preferably from 0.304 to 0.357 g/m² and much more preferably from 0.314 to 0.347 g/m² when the composition is applied to a surface so that the thickness of the dried layer is about 1 to 3 μm.

The pigments are preferably used in a form of dispersion liquid. The dispersion liquid may be prepared by adding a composition, preliminarily prepared by mixing the pigment and a pigment dispersant, to an organic solvent (or vehicle) described later for dispersion. The vehicle herein refers to a portion of medium allowing the pigments to disperse therein when the coating material is in a liquid state, and includes a liquidous portion (binder) binding with the pigment to thereby solidify a coated layerwand a component (organic solvent) dissolving and diluting the liquidous portion. There is no special limitation on dispersion machine used for dispersing the pigment, and any known dispersers such as kneader, roll mill, attoritor, super mill, dissolver, homomixer, sand mill and the like, can be used.

The colorant (pigment) used in the present invention preferably has a particle diameter not greater than 0.1 μm, and more preferably not greater than 0.08 μm.

### (5) Other Ingredients

### —Solvent—

The colored photosensitive polymer composition may comprise organic solvent with the retardation controlling agent and the (1) to (4) ingredients described above. Examples of the organic solvent include methyl ethyl ketone, propylene glycol monomethyl ether, propylene glycol monomethyl ether acetate, cyclohexanone, cyclohexanol, methyl isobutyl ketone, ethyl lactate, methyl lactate and caprolactam.

### —Surfactant—

The colored photosensitive polymer composition, which can be applied to a surface of a polymer film or a glass plate by using slit-like nozzle, may further comprise a surfactant with the retardation controlling agent for controlling the film thickness to be uniform, and prevent effectively coating unevenness. As the surfactant, those described in Japanese Laid-Open Patent Publication “Tokkai” Nos. 2003-337424 and H11-133600 may be suitably used.

The content of the surfactant in the colored photosensitive composition is generally 0.001-1%, preferably 0.01-0.5%, particularly preferably 0.03-0.3% relative to the total solid content of the composition.

### —Thermal Polymerization Inhibitor—

The colored photosensitive polymer color composition may comprise a thermal polymerization inhibitor. Examples of the thermal polymerization inhibitor include hydroquinone, hydroquinone monomethylether, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), 2-mercaptobenzimidazole and phenothiazine.

When a thermal polymerization inhibitor is used, the content thereof relative to the total solid content of the colored photosensitive polymer composition is generally 0.01-1%, preferably 0.02-0.7%, particularly preferably 0.05-0.5%.

### —Dyes and Pigments to be Used Secondarily—

The colored photosensitive polymer composition may, further comprise at least an ingredient (dye or pigment) selected from known colorants with the aforementioned colorant (pigment), if necessary. When a known pigment is used, the pigment is preferably dispersed in the colored photosensitive polymer composition uniformly; and in terms of dispersion, the particle diameter of the pigment is preferably not larger than 0.1 μm, and more preferably not larger than 0.08 μm.

Examples of the known dye and pigment include Victoria Pure blue BO(C.I. 42595), Auramine (C.I. 41000), Fat black HB(C.I. 26150), Monolight Yellow GT(C.I. pigment yellow 12), Permanent Yellow GR(C.I. pigment yellow 17), Permanent Yellow HR(C.I. pigment yellow 83), Permanent Carmine FBB(C.I. pigment red 146), C.I. pigment violet 19, Permanent Ruby FBH(C.I. pigment red 11), C.I. pigment red 81, C.I. pigment-blue 15, Monolight First black B(C.I. pigment black 1), Carbon, C.I. pigment red 97, C.I. pigment red 122, C.I. pigment red 149, C.I. pigment red 168, C.I. pigment red 177, C.I. pigment red 180, C.I. pigment red 192, C.I. pigment red 215, C.I. pigment green 7, C.I. pigment blue 15:1, C.I. pigment blue 15:4, C.I. pigment blue 22, C.I. pigment blue 60, C.I. pigment blue 64, and C.I. pigment violet 23.

Among these, C.I. pigment violet 23 is preferably added to the R colored photosensitive polymer composition, and its preferable content is 0.5 to 5% with respect to the mass of R pigment (C.I.P.R.

254); and C.I. pigment violet is preferably added to the B colored photosensitive polymer composition, and its preferable content is 0.2 to 10% with respect to the mass of B pigment (C.I.P.B. 15:6).

### —UV Ray Absorber—

The colored photosensitive polymer composition may further comprise a UV ray absorber, if necessary. Examples of the ultraviolet absorber include compounds described in Japanese Laid-Open Patent Publication “Tokkai” No. H5-72724, and salicylate-based, benzophenone-based, benzotriazole-based, cyanoacrylate-based, nickel chelate-based and hindered amine-based compounds

In particular, its examples include phenylsalicylate, 4-t-butylphenylsalicylate, 2,4-di-t-butylphenyl-3′,5′-di-t-4′-hydroxybenzoate, 4-t-butylphenylsalicylate, 2,4-dihydroxybenzophenone, 2-hydroxy-4-methoxybenzophenone, 2-hydroxy-4-n-octoxybenzophenone, 2-(2′-hydroxy-5′-methylphenyl) benzotriazole, 2-(2′-hydroxy-3′-t-butyl-5′-methylphenyl)-5-chlorobenzotriazole, ethyl-2-cyano-3,3-di-phenyl acrylate, 2,2′-hydroxy-4-methoxybenzophenone, nickel dibutyldithiocarbamate, bis(2,2,6,6-tetramethyl-4-pyridine)-sebacate, 4-t-butylphenyl salicylate, phenyl salicylate, 4-hydroxy-2,2,6,6-tetramethylpiperidine condensate, succinic acid-bis(2,2,6,6-tetramethyl-4-piperidenyl)-ester, 2-[2-hydroxy-3,5-bis(α,α-dimethylbenzyl)phenyl]-2H-benzotriazole, 7-{[4-chloro-6-(diethylamino)-5-triazine-2-yl]amino}-3-phenylcoumalin.

When an ultraviolet absorber is used, the content of the ultraviolet absorber relative to the total solid content of the colored photosensitive polymer composition is generally 0.5-15%, preferably 1-12%, particularly preferably 1.2-10%.

The colored photosensitive polymer composition may further comprise one or more additives other than the above mentioned ingredients, such as “adhesion aid” described in Japanese Laid-open patent publication “Tokkai” No. H 11-133600.

### [Photosensitive Transfer Material]

The photosensitive transfer material of the invention comprises a photosensitive polymer layer formed of the photosensitive polymer composition. After transferred onto a surface of a liquid crystal substrate or the like, the photosensitive polymer layer is subjected to photo-irradiation and development, and, then, becomes part (a sub-pixel or a domain included in a sub-pixel) of a color filter layer. The photosensitive polymer layer may be formed on a temporary support such as a polymer film by ejecting the photosensitive polymer composition in a strip shape from a slit-like nozzle onto a surface of the support, and drying it on the surface. In terms of ejection from a slit-like nozzle, the photosensitive polymer composition is preferably prepared as a liquid.

### (Slit-Like Nozzle)

The slit-like nozzle which can be employed in the above-mentioned method has a slit-like hole in the part from which fluid is ejected. In particular, slit-like nozzles and slit coaters described in Japanese Laid-open patent publication “Tokkai” Nos. 2004-89851, 2004-17043, 2003-170098, 2003-164787, 2003-10767, 2002-79163 and 2001-310147 are preferably employed.

As mentioned above, it is possible to align molecules of the retardation controlling agent along with a moving direction of the temporary support or along with a direction perpendicular to the moving direction by properly controlling a liquid viscosity and a flow velocity of the photosensitive polymer composition when it is ejected from a slit-like nozzle, a slit width and a moving velocity of a temporary support which is applied with the photosensitive polymer composition, and, then, it is also possible to form a photosensitive polymer layer exhibiting a desired retardation.

There is no limitation on the construction of the photosensitive transfer material of the invention so far as it comprises a photosensitive polymer layer formed of the photosensitive polymer composition described above. The transfer material may further comprise at least one layer other than the photosensitive polymer layer, or, for example, it may have an integral construction as described in Japanese Laid-open Patent Publication “Tokkai” No. H05-72724. One example of the integral construction is a construction having a layered structure of a temporary support/a thermoplastic polymer layer/an intermediate layer/a photosensitive polymer layer/a protective film in this order.

### (Temporary Support)

The temporary support to be used in the invention is required to exhibit flexibility without significant deformation, shrinkage or elongation under pressure or under pressure and heating. Examples of such a temporary support include polyethylene terephthalate films, tri acetate cellulose films, polystyrene films and polycarbonate films. Among those, biaxially stretched polyethylene terephthalate films are preferred.

### (Thermoplastic Polymer Layer)

Examples of the ingredient to be used for preparing the thermoplastic polymer layer include polymer substances disclosed in Japanese Laid-Open Patent Publication “Tokkai” No. hei 5-72724. The ingredient is particularly preferably selected from organic polymer substances having softening points, measured by the Vicat method (more specifically, a method of measuring softening point of polymer conforming to ASTMD1235 authorized by American Society For Testing and Materials) of approximately 80° C. or below. More specifically, organic polymers such as polyolefins including polyethylene and polypropylene; ethylene copolymers including those composed of ethylene and vinyl acetate or saponified product thereof, or composed of ethylene and acrylate ester or saponified product thereof; polyvinyl chloride; vinyl chloride copolymers including those composed of vinyl chloride and vinyl acetate or saponified product thereof; polyvinylidene chloride; vinylidene chloride copolymer; polystyrene; styrene copolymers including those composed of styrene and (meth)acrylate ester or saponified product thereof; polyvinyl toluene; vinyltoluene copolymers such as being composed of vinyl toluene and (meth)acrylate ester or saponified product thereof; poly (meth)acrylate ester; (meth)acrylate ester copolymers including those composed of butyl (meth)acrylate and vinyl acetate; vinyl acetate copolymers; and polyamide polymers including nylon, copolymerized nylon, N-alkoxymethylated nylon and N-dimethylamino-substituted nylon.

The thickness of the dried thermoplastic polymer layer usually ranges from 2 to 30 μm, preferably from 5 to 20 μm, and more preferably from 7 to 16 μm.

The thermoplastic polymer layer may be disposed between the temporary support and the photosensitive polymer layer; and, after the photosensitive polymer layer is transferred onto a substrate, the thermoplastic polymer layer may be removed together with the temporary support from the photosensitive polymer or be transferred together with the photosensitive polymer layer onto a substrate once and then be removed.

### (Intermediate Layer)

According to the photosensitive transfer material of the present invention, it is preferable to provide an intermediate layer for the purpose of preventing mixing of the components during coating of a plurality of layers and during storage after the coating. The oxygen shut-off film having oxygen shut-off function described as a “separation layer” in Japanese Laid-Open Patent Publication “Tokkaihei” No. 5-72724 is preferably used, by which sensitivity during the light exposure increases, and this improves the productivity.

Any films showing a low oxygen permeability and being dispersible and soluble to water or aqueous alkaline solution are preferably used as the oxygen shut-off film, and such films can properly be selected from any known films. Of these, particularly preferable is a combination of polyvinyl alcohol and polyvinyl pyrrolidone.

The thickness of the dried intermediate layer usually ranges from 0.2 to 5 μm, preferably from 0.5 to 3 μm, and more preferably from 1 to 2.5 μm.

The intermediate layer may be disposed between the temporary support (or the thermoplastic polymer layer in the embodiment comprising the thermoplastic polymer layer disposed on the temporary support) and the photosensitive polymer layer; and, after the photosensitive polymer layer is transferred onto a substrate, it may be removed together with the temporary support from the photosensitive polymer or be transferred together with the photosensitive polymer layer onto a substrate once and then be removed.

### (Protective Film)

On the photosensitive polymer layer, it is preferable to provide a thin protective film for the purpose of preventing contamination or damage during storage. The protective film may be composed of a material same as, or similar to, that used for the temporary support, but must be readily separable from the polymer layer. Preferable examples of the material composing the protective film include silicon paper, polyolefin sheet and polytetrafluoroethylene sheet.

The thickness of the protective film usually ranges from 4 to 40 μm, preferably from 5 to 30 μm, and more preferably from 10 to 25 μm.

### (Method for Producing Photosensitive Transfer Material)

One example of the photosensitive transfer material of the invention is an integral film having a lamination of a temporary support, a thermoplastic polymer layer, an intermediate layer and a photosensitive polymer layer in this order, and such a photosensitive transfer material may be produced according to methods described below.

A thermoplastic polymer layer is prepared by applying a coating liquid, which is prepared by dissolving ingredients for a thermoplastic polymer layer in a solvent, referred to as “coating liquid for a thermoplastic polymer layer”, to a surface of the temporary support and drying it; then, an intermediate layer is prepared on the thermoplastic polymer layer by applying a coating liquid, which is prepared by dissolving ingredients for an intermediate layer in a solvent in which the thermoplastic polymer layer is hardly dissolved, to the surface of the thermoplastic polymer layer and drying it; and, then, a photosensitive polymer layer is prepared in the same manner described above. The photosensitive polymer composition may be applied to a surface through a slit-like nozzle, and, so, is preferably prepared as a fluid. The solvent which is used for preparing the fluid is preferably selected from solvents in which the intermediate layer is hardly dissolved.

The photosensitive transfer material of the invention can be also prepared according to a laminating method, for example, as follows.

Two sheets, one is a sheet of a temporary support having a thermoplastic polymer layer and an intermediate layer thereon and another is a sheet of a protective film having a photosensitive polymer layer thereon, are prepared, and laminated so that the intermediate layer and the photosensitive layer contact each other; or, two sheets, one is a sheet of a temporary support having a thermoplastic polymer layer thereon and another is a sheet of a protective film having a photosensitive polymer layer and an intermediate layer thereon, are prepared, and laminated so that the thermoplastic polymer layer and the intermediate layer contact each other.

### [Process for Producing Color Filter]

The present invention also relates to a process for producing a color filter. One embodiment of the process of the invention comprises a step of forming a photosensitive polymer on a surface of a substrate; a step of exposing the layer at least one time; a step of developing the layer at least one time by removing the exposed or un-exposed portion thereof to form a predetermined pattern; and a step of baking the layer at least one time by heating the patterned photosensitive polymer layer to harden it.

### (Step of Forming Photosensitive Polymer Layer)

The photosensitive polymer layer is preferably formed on a substrate according to (a) a coating method or (b) a transferring method employing a transfer material of the invention.

(a) Coating Method

According to the coating method, the photosensitive polymer layer can be formed on a surface of a substrate by applying a colored photosensitive polymer composition comprising a retardation agent to the surface with a known coating equipment, and then drying it. In order to align molecules of the retardation agent so as to develop desired retardation, slit-coaters are preferably used for applying it to a surface. Preferred examples of the slit coater to be employed are same as those to be employed for producing the photosensitive transfer material.

(b) Transferring Method

According to the transferring method, the photosensitive polymer layer can be formed on a surface of a substrate by transferring the photosensitive polymer layer from on the temporary support of the photosensitive transfer material onto a substrate. More specifically, the photosensitive polymer layer can be formed on a surface of a substrate by disposing the photosensitive transfer material on the surface of the substrate so that the surface of the photosensitive polymer layer is faced to the surface of the substrate, then pressing under heating or no-heating with rollers or flat plates them to bond them, and then removing the temporary support or the like. Specific examples of the laminator and the method of lamination include those described in Japanese Laid-Open Patent Publication Nos. 7-110575, 11-77942, 2000-334836 and 2002-148794, wherein the method described in Japanese Laid-Open Patent Publication No. 7-110575 is preferable in view of low contamination.

Using a material transparent for the light to be employed in exposing as a temporary support, the temporary support or the like may be removed anytime before or after exposing.

### (Substrate)

The substrate which is a target for transferring of the transfer material of the present invention can be a transparent substrate, which is exemplified for example by known glasses such as soda glass sheet having a silicon oxide film formed on the surface thereof, low-expansion glass and non-alkali glass; or plastic film. The target substrate can be improved in adhesiveness with the photosensitive transfer material, or the colored photosensitive polymer composition, by being preliminarily subjected to a coupling treatment. The coupling treatment is preferably carried out by using the method described in Japanese Laid-Open Patent Publication “Tokkai” No. 2000-39033.

### (Oxygen Shut-Off Film)

An oxygen shut-off film may be formed on the photosensitive polymer layer. It contributes to increasing the exposing sensitivity. Examples of the oxygen shut-off film are same as those described in the (Intermediate Layer) section of the [Photosensitive transfer material] section.

### (Step of Exposure and Development)

Next, the photosensitive polymer layer is subjected to light-exposure and development to form a predetermined pattern shape. More specifically, the light exposure may be carried out for example as follows.

A predetermined mask is disposed on or over the photosensitive polymer layer formed on the substrate. And the photosensitive polymer layer is irradiated with light from above the mask (and other layers such as a thermoplastic polymer layer and an intermediate layer, when the photosensitive polymer layer having the layers thereon is irradiated) and, then, is developed with a developer and is removed the exposed or non-exposed portion therefrom to form a predetermined pattern shape. A light source for the light exposure herein can properly be selected from those capable of illuminating light which has a sufficient intensity and a sufficient wavelength-range for initiating the chemical reaction which results in a significant difference in solubility against a developer between the exposed and non-exposed portions of the photosensitive polymer layer and can make it developable. When the photosensitive polymer layer is cured by light-exposing, a light source capable of illuminating light having a wavelength range capable of curing the polymer layer (365 nm, 405 nm, for example) may be employed. Specific examples of the light source include extra-high voltage mercury lamp, high voltage mercury lamp and metal halide lamp. Energy of exposure generally falls in the range from 5 to 200 mJ/cm² or around, and preferably from 10 to 100 mJ/cm² or around.

A developer (developing solution) used in the development step after the light exposure is not specifically limited, allowing use of any known developing solution such as those described in Japanese Laid-Open Patent Publication “Tokkaihei” No. 5-72724. The developing solution is preferably such as allowing the polymer layer to show a dissolution-type developing behavior, and preferably such as containing a compound having pKa=7 to 13 to a concentration of 0.05 to 5 mol/L, for example. A small amount of an organic solvent miscible with water may be added to the developer.

Examples of the organic solvent miscible with water include methanol, ethanol, 2-propanol, 1-propanol, butanol, diacetone alcohol, ethylene glycol monomethyl ether, ethylene glycol monoethyl ether, ethylene glycol mono-butyl ether, benzyl alcohol, acetone, methyl ethyl ketone, cyclohexanone, ε-caprolactone, γ-butyrolactone, dimethylformamide, dimethyl acetamide, hexamethyl phosphorylamide, ethyl lactate, methyl lactate, ε-caprolactam, and N-methylpyrrolidone. The concentration of the organic solvent is preferably adjusted to 0.1% by mass to 30% by mass.

The above-described developing solution can be added with any known surfactant. The concentration of the surfactant is preferably adjusted to 0.01% by mass to 10% by mass.

The development may be carried out according to any known method such as paddle development, shower development, shower-and-spin development and dipping development.

The shower development will be described in more detail. The non-exposed portion can be removed by showering a development fluid on the exposed portion of the photosensitive polymer layer. If the photosensitive layer has any unnecessary layer such as a thermoplastic polymer layer and a medium layer thereon, such a layer may be removed by showering an alkali fluid, for which the photosensitive polymer layer shows a low solubility, on the surface prior to the development. The development residue may be removed by showering a cleaning agent on the surface and rubbing the surface with a brush after the development.

The temperature of the developer preferably ranges from 20° C. to 40° C., and its pH preferably ranges from 8 to 13.

According to a sequence of the step of forming a photosensitive polymer layer, the step of exposing and the step of developing described above, a colored sub-pixel can be formed. The color filter of the invention can be produced by repeating the sequence plural times as the number of the colors of the sub-pixels. A colored sub-pixel with multi-domains exhibiting a different retardation each other can be formed by repeating the sequence plural times.

### (Step of Baking)

Baking step is carried out after developing to improve the film-strength. Baking may be carried out after each colored sub-pixel is formed or after all colors of sub-pixels are formed. Baking is preferably carried out both of after each colored sub-pixel is formed and after all colors of sub-pixels are formed. In particular, baking is a so-called heating treatment for completing the reaction of monomer or oligomer residue, and may be carried out at an appropriate temperature for an appropriate time. Usually, the baking step after each color is formed may be carried out by heating the target at a temperature ranging from 200 to 240° C. for 10 to 20 minutes; and the baking step after all colors are formed may be carried out by heating the target at a temperature ranging from 200 to 240° C. for 30 to 180 minutes. Avoiding significant yellowing due to baking and worsening the production task, the temperature and the time are set as high as and as short as possible respectively.

Next, one example of the process for producing a color filter of the invention will be described.

i) Cleaning Substrate

A non-alkali glass substrate was cleaned using a rotating nylon-haired brush while being blasted with a shower of a glass cleaner solution (e.g., “T-SD1” and “T-SD2” (trade name; product of FUJIFILM Corporation), conditioned at 25° C. for 20 seconds, then showered with purified water.

ii) Silane Coupling Treatment

In order to enhance the adhesion of the photosensitive polymer layer by the lamination, the surface of the substrate is preferably subjected to a silane coupling treatment. Silane coupling agents having a function group capable of interacting with the photosensitive polymer layer are used preferably. For example, a glass substrate is blasted with a shower of a silane coupling solution (0.3% aqueous solution of N-β-(aminoethyl)-γ-aminopropyl trimethoxysilane, trade name: KBM-603, Shin-Etsu Chemical Co., Ltd.) for 20 seconds, and then washed with a shower of purified water, and then heated to initiate the reaction.

A heating bath may be used, and the substrate of a laminator may be preheated to initiate the reaction.

Usually, the treatment is carried our before the first color is formed, however, if necessary, for example when the adhesion after lamination is weak, the treatment may also be carried out before another color is formed.

iii) Lamination

The substrate is then heated in a substrate preheating heater at 100° C. for 2 minutes, and then fed into a laminator. In this way, the uniform lamination can be carried out.

The above-described transfer material, from which a protective film is removed, is laminated onto the substrate preheated at 100° C. for 2 minutes, using a laminator under a rubber roller temperature of 130° C., a line pressure of 100 N/cm and a travel speed of 2.2 m/min. When the rubber roller temperature is equal to or higher than 150° C., some wrinkles may be formed in the photosensitive transfer material; and when the rubber roller temperature is equal to or lower than 100° C., the adhesion of the photosensitive transfer material may be weak.

iv) Light Exposure

After the temporary support is removed therefrom, the entire surface thereof was then subjected to light exposure using a proximity-type exposure apparatus having an extra-high-voltage mercury lamp. When the size of the substrate is equal to or more than 50 cm, in terms of avoiding deflection of a photomask, it is preferred that the substrate and a photomask, which is a quartz exposure mask having a image pattern thereon, are vertically held while being subjected to light exposure. Although better resolution can be obtained as the distance between the surface of the photomask and the surface of the photosensitive polymer layer is shorter, foreign materials are more easily mixed therein. And, so, the distance may be set to range from 100 to 300 μm. The amount of the light exposure preferably ranges from 10 to 80 mJ/cm². In this way, the photosensitive transfer material can be subjected to light exposure in a patterned manner.

v) Removal of Thermoplastic Polymer Layer and Intermediate Layer

The thermoplastic polymer layer and the intermediate layer may be removed with triethanolamine-base developing solution (containing 2.5% of triethanolamine, a nonionic surfactant, and a polypropylene-base defoaming agent, trade name: T-PD1, product of Fujifilm Corporation). At this time, in order to avoid developing the photosensitive polymer layer ideally, the conditions may be decided. For example, the developing solution is showered at 30° C. for 50 seconds, under a flat nozzle pressure of 0.04 MPa.

vi) Development of Photosensitive Polymer Layer

Thereafter, the photosensitive polymer layer is developed using an alkali solution to thereby form an image. For example, a sodium carbonate-base developing solution (containing 0.06 mol/L of sodium hydrogencarbonate, sodium carbonate of the same concentration, 1% of sodium dibutylnaphthalene sulfonate, anionic surfactant, defoaming agent and stabilizer, trade name: T-CD1, product of Fujifilm Corporation) is used.

The development may be carried out with a shower under a conical nozzle pressure of 0.15 MPa at 35° C. for 35 seconds. KOH-type or TMAH-type development solution may also be used.

vii) Removal of Residues

Subsequently, a cleaning agent (containing phosphate, silicate, nonionic surfactant, defoaming agent and stabilizer, trade name: T-SD1 (product of Fujifilm Corporation; or containing sodium carbonate and a phenoxy polyoxyethylene-type surfactant, trade name: T-SD2 (product of Fujifilm Corporation) may be used. The residues may be removed by rubbing the surface with a rotating nylon-haired brush while being blasted with a shower of the agent under a conical nozzle pressure of 0.02 MPa at 33° C. for 20 seconds. In this way, the residues of the photosensitive polymer layer in non-irradiated portions can be removed.

viii) Post-Exposure

Subsequently, the substrate may be further subjected to post-exposure from the polymer layer side thereof using an extra-high-voltage mercury lamp under an exposure energy of 500 mJ/cm², and may be then annealed. The post-exposure may be subjected from the both sides, and the exposure energy may range from 100 to 800 mJ/cm². The post-exposure may contribute to improvement in polymerization effect in a next step, a baking step, and can adjust the cross-section shape of each pixel, which is obtained after the baking step, by the amount of post-exposure.

ix) Baking

Baking may be carried out to promote the reaction of monomers or oligomers and obtain a harden film. The baking interval between forming one color layer and forming another color layer may be carried out at a temperature ranging from 200 to 240° C. for a period ranging from 10 to 20 minutes; the baking after all color layers are formed may be carried out at a temperature ranging from 200 to 240° C. for a period ranging from 30 to 180 minutes. Avoiding significant yellowing due to baking and worsening the production task, the temperature and the time are set as high as and as short as possible respectively.

According to the above steps, the color filter of the invention can produced.

After the all color filter layers are produced, if necessary, a black matrix may be formed on the borderline which divides the color filter layers. The black matrix may be prepared according to various known method such as a transfer method, a printing method and an ink-jet method.

All sub-pixels (for examples, sub-pixels of all of the red (R), green (g) and blue (B)) of the color filter of the invention may be formed of the photosensitive polymer layer containing a retardation controlling agent, or may comprise some sub-pixels or some domains which are formed of a photosensitive polymer layer not containing a retardation controlling agent.

One example of the color filter of the invention is a color filter of which retardation exhibits a different dependency on a wavelength of between light in a normal direction and in an oblique direction such as a direction at a polar angle of 60 degree. According to the invention, the retardation wavelength-dependency property of the color filter actively contributes to optical compensation. The scope of the invention is not limited for a liquid crystal layer mode, the invention may be employed in any mode LCD such as a VA, IPS, ECB, TN and OCB mode liquid crystal display (LCD).

The invention also relates to the LCD comprising the color filter of the invention. The LCD may employ a transmissive mode, semi-transmissive mode or reflective mode. The LCD may employ any displaying modes such as a VA, IPS, ECB, TN and OCB modes.

The color filter of the invention comprises sub-pixels which are adjusted their retardation to the optimum range, and, therefore, the LCD employing the color filter can be precisely compensated optically. As a result, according to the invention, it is possible to provide a LCD which is improved in contrast in a normal direction and viewing-angle properties, especially reduced in color-shift generated in an oblique direction in the black state.

The LCD of the invention may comprise at least one retardation plate disposed outside of the liquid crystal cell.

Employing the retardation plate(s) disposed outside of the liquid crystal cell, the retardation plate disposed outside of the liquid crystal cell may have retardation which can contribute to optical compensation mainly; and the color filter may have a retardation which is required as a corrective value with respect to each color (sub-pixel) or each domain. According to this embodiment, it is possible to obtain the effect of the invention without thickening the color filter layer extremely or increasing the addition amount of the retardation controlling agent extremely.

### EXAMPLES

Paragraphs below will more specifically describe the present invention referring to Examples. Any materials, reagents, amount and ratio of use and operations shown in Examples may appropriately be modified without departing from the spirit of the present invention. It is therefore understood that the present invention is by no means limited to specific Examples below.

It is to be noted that the terms “part”, “%” and “molecular weight” mean “part by mass”, “mass %” and “weight-average molecular weight” respectively as long as there is no notation.

### Example 1

### —Method of Preparing Photosensitive Transfer Material for Forming Black Matrix—

A polyethylene terephthalate base film (PET base film), having a thickness of 75 μm, was prepared; and a coating fluid for forming a thermoplastic polymer layer was prepared by mixing the ingredients shown below. And the coating fluid was applied to the surface of the base film with a slit-coater and dried in an oven at 120° C. for 5 minutes to form a thermoplastic polymer layer having a thickness of 15 μm on the PET base film.

[Formulation of Coating Fluid for Thermoplastic Polymer Layer]

| | |
|---|---|
| Copolymer of benzyl methacrylate/2-ethylhexyl acrylate/ | 4.5 parts |
| methylmethacrylate/methacrylic acid | |
| (polymerization molar ratio: 4.5/11.7/55/28.8; | |
| molecular weight: 80000) | |
| Copolymer of styrene/acrylic acid | 15 parts |
| (polymerization molar ratio: 60/40; | |
| molecular weight: 8000) | |
| 2,2-bis[4-(methacryloxy polyethoxy)phenylpropane] | 7 parts |
| F-176PF | 1.5 parts |
| (Fluorochemical Surfactant manufactured | |
| by DAINIPPON INK AND CHEMICALS, | |
| INCORPORATED) | |
| Propylene glycol monomethyl ether | 28 parts |
| Methyl ethyl ketone | 27 parts |

A coating fluid for forming an intermediate layer was prepared by mixing the ingredients shown below, applied to the surface of the thermoplastic polymer layer with a slit coater, and, then, dried in an oven at 100° C. for 2 minutes to form an intermediate layer having a thickness of 1.6 μm on the thermoplastic polymer layer.

[Formulation of Coating Fluid for Intermediate layer]

| | |
|---|---|
| Polyvinyl alcohol | 13 parts |
| (PVA-205 manufactured by Kuraray Co., Ltd.) | |
| Polyvinyl pyrrolidone | 6 parts |
| (PVP-K30 manufactured by GOKYO TRADING CO., LTD.) | |
| Methanol | 173 parts |
| Ion-exchanged water | 211 parts |

A coating fluid for forming a light-blocking photosensitive polymer layer was prepared by mixing the ingredients shown below, applied to the surface of the intermediate layer with a slit coater, and dried in an oven at 100° C. for 2 minutes to form a light-blocking photosensitive polymer layer having a thickness of 3 μm on the intermediate layer. A poly propylene film having a thickness of 12 μm was bond to the surface of the light-blocking photosensitive polymer layer by lamination at the room temperature as a cover film. In this way, a photosensitive transfer material for forming black matrix, consisting of a PET base film having a thermoplastic polymer layer, an intermediate layer, and a light-blocking photo-sensitive polymer layer in this order thereon, was produced.

[Formulation of Coating Fluid for Light-blocking Photosensitive
Polymer Layer]

| | | |
|---|---|---|
| SPB-10 | 20.97 | parts |
| (C.I.PB60 dispersion fluid, manufactured by FUJIFILM | | |
| Corporation) | | |
| YT-20 | 6.38 | parts |
| (C.I.PY139 dispersion fluid, manufactured by FUJIFILM | | |
| ELECTRONIC MATERIALS CO., LTD.) | | |
| RT-2-2 | 1.74 | parts |
| (C.I.PB15:6 dispersion fluid, manufactured by | | |
| FUJIFILM ELECTRONIC MATERIALS CO., LTD.) | | |
| CFP-FF-802V | 2.98 | parts |
| (C.I.PV23, manufactured by FUJIFILM | | |
| ELECTRONIC MATERIALS CO., LTD.) | | |
| 7270M | 8.37 | parts |
| (Carbon Black dispersion fluid, manufactured by | | |
| Mikuni Color Works, Ltd.) | | |
| MMPG-AC | 17.61 | parts |
| (propylene glycol monomethyl ether acetate) | | |
| Methyl ethyl ketone | 34.76 | parts |
| Surfactant | 0.07 | parts |
| (Megafac F-176PF manufactured by Dainippon Ink | | |
| and Chemicals, Inc.) | | |
| Hydroquinone monomethyl ether | 0.0021 | parts |
| Dipentaerythritol hexaacrylate | 4.53 | parts |
| 9-phenyl acridine | 0.23 | parts |
| 2-mercapto-5-methylmercapto-1,3,4-thiadiazole | 0.23 | parts |

### —Method of Preparing Photosensitive Transfer Material for Forming Colored Sub-Pixels—

Three photosensitive transfer materials for forming red, green and blue sub-pixels were produced respectively in the same manner of the photosensitive transfer material for forming black matrix, except that coating fluids for forming a red, green and blue photosensitive polymer layers were used respectively in the place of “the coating fluid for forming a light-blocking photosensitive polymer layer”.

In the formulations of the coating fluids shown below, Retardation controlling agent A and Retardation controlling agent B are as follows.

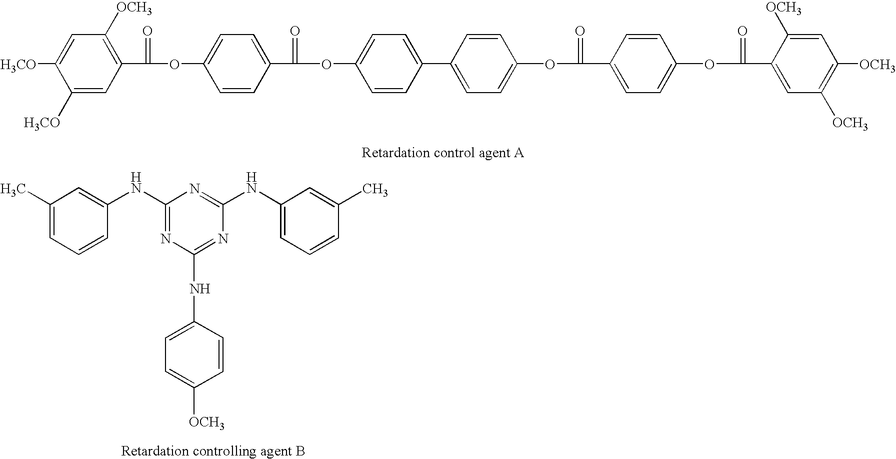

[Formulation of Coating Fluid for Red Photosensitive Polymer Layer]

| | | |
|---|---|---|
| RT-107 | 21.65 | parts |
| (C.I. PR254 dispersion fluid manufactured by FUJIFILM | | |
| ELECTRONIC MATERIALS CO., LTD.) | | |
| MMPG-AC | 31.20 | parts |
| (propylene glycol monomethyl ether acetate) | | |
| Methyl ethyl ketone | 34.96 | parts |
| Surfactant | 0.06 | parts |
| (Megafac F-176PF manufactured by Dainippon Ink | | |
| and Chemicals, Inc.) | | |
| Phenothiazine | 0.0012 | parts |
| Copolymer of benzyl methacrylate/methacrylic acid | 4.97 | parts |
| (copolymerization molar ratio: 72/28 | | |
| weight-average molecular weight: 30,000) | | |
| Dipentaerythritol hexaacrylate | 4.92 | parts |
| 2-trichloromethyl-5-(p-styrylstyryl)-1,3,4-oxadiazole | 0.31 | parts |
| 7-{[-4(diethylamino)-6-(3-hydroxymethyl pyperidino)- | 1.50 | parts |
| s-triazinyl (2)]-amino}-3-phenyl coumarin | | |
| 2,4,6-tris [2,4-bis(methoxycarbonyloxy)phenyl]-1,3,5- | 0.37 | parts |
| triazine | | |
| Retardation controlling agent A | 3.00 | parts |

[Formulation of Coating Fluid for Green Photosensitive Polymer
Layer]

| | | |
|---|---|---|
| GT-2 | 15.86 | parts |
| (C.I. PG36 dispersion fluid manufactured by FUJIFILM | | |
| ELECTRONIC MATERIALS CO., LTD.) | | |
| YT-123 | 11.06 | parts |
| (C.I. PY138 dispersion fluid manufactured by FUJIFILM | | |
| ELECTRONIC MATERIALS CO., LTD.) | | |
| MMPG-AC | 10.25 | parts |
| (propylene glycol monomethyl ether acetate) | | |
| Methyl ethyl ketone | 51.49 | parts |
| Surfactant | 0.19 | parts |
| (Megafac F-176PF manufactured by Dainippon Ink | | |
| and Chemicals, Inc.) | | |
| Phenothiazine | 0.004 | parts |
| Copolymer of benzyl methacrylate/methacrylic acid | 4.47 | parts |
| (copolymerization molar ratio: 72/28 | | |
| weight-average molecular weight: 30,000) | | |
| Dipentaerythritol hexaacrylate | 5.27 | parts |
| 2-trichloromethyl-5-(p-styrylstyryl)-1,3,4-oxadiazole | 0.193 | parts |
| 7-{[-4(diethylamino)-6-(3-hydroxymethylpyperidino)-s- | 1.26 | parts |
| triazinyl(2)]-amino}-3-phenyl coumarin | | |
| Retardation controlling agent A | 1.20 | parts |

[Formulation of Coating Fluid for Blue Photosensitive Polymer Layer]

| | | |
|---|---|---|
| 7075M | 32.93 | parts |
| (C.I. PB15: 6 dispersion fluid manufactured by | | |
| Mikuni Color Works, Ltd.) | | |
| MMPG-AC | 0.69 | parts |
| (propylene glycol monomethyl ether acetate) | | |
| Methyl ethyl ketone | 52.50 | parts |
| Surfactant | 0.12 | parts |
| (Megafac F-176PF manufactured by Dainippon Ink | | |
| and Chemicals, Inc.) | | |
| Phenothiazine | 0.012 | parts |
| Copolymer of benzyl methacrylate/methacrylic acid | 8.10 | parts |
| (copolymerization molar ratio: 78/22 | | |
| weight-average molecular weight: 40,000) | | |
| Dipentaerythritol hexaacrylate | 5.19 | parts |
| 2-trichloromethyl-5-(p-styrylstyryl)-1,3,4-oxadiazole | 0.20 | parts |
| 2,4,6-tris[2,4-bis(methoxycarbonyloxy)phenyl]-1,3,5- | 0.25 | parts |
| triazine | | |
| Retardation controlling agent B | 2.00 | parts |

### —Method for Producing Color Filter—

A glass substrate was immersed in a silane coupling solution (1%-diluted solution of “KBM-603”, trade name, manufactured by Shin-Etsu Chemical Co., Ltd.) for three minutes, washed with a shower of purified water for 10 seconds, and, after water being removed with an air gun therefrom, heated in an oven at 110° C. for 5 minutes. In this way, a silane-coupling treated glass substrate was produced.

The photosensitive transfer material for forming red sub-pixels, from which the cover film was removed, was laid on the silane-coupling treated glass substrate so that the surface of the photosensitive layer contacted the surface of the substrate, and bonded to the surface of the substrate by a laminator (First-Laminator 8B-550-80 manufactured by Taisei laminator Co., Ltd.) under a pressurization at 2 kg/m² and heating at a roller temperature of 130° C. with a feeding rate of 0.2 m/min. After that, the temporary support, polyethylene terephthalate film, was removed from other layers at an interface between the temporary support and the thermoplastic polymer layer. The photosensitive polymer layer was irradiated with light (irradiation energy: 20 mJ/cm²) from an ultrahigh pressure mercury lamp (2 kw) through a photo-mask for red sub-pixels by using an aligner (“MAP-1200L” manufactured by DAINIPPON SCREEN MFG. CO., LTD.) at the position far from the surface of the layer by 60 cm for three seconds. Subsequently, the thermoplastic polymer layer and the intermediate layer were removed from the photosensitive layer by using a treatment liquid (10-times diluted liquid of “T-PD2” manufactured by FUJIFILM Corporation). After that, the photosensitive layer was subjected to development by using a treatment liquid (5-times diluted liquid of “T-CD1” manufactured by FUJIFILM Corporation); and the un-irradiated parts were removed. The undeveloped residual parts were also removed by using a treatment liquid (10-times diluted liquid of “T-SD1” manufactured by FUJIFILM Corporation) while being brushed. In this way, a red sub-pixel pattern was formed on the glass substrate. The substrate as a whole was subjected to a post-exposure treatment, in particular, irradiated with light (500 mJ/cm² irradiation energy) from both surface sides by using an aligner for promoting curing of the sub-pixel pattern, and baked in an oven at 220° C. for 20 minutes.

Next, the photosensitive transfer material for forming green sub-pixels, from which the cover film was removed, was laid on the glass substrate having the red sub-pixel pattern thereon, and, then, steps of removal of the temporary support, patterned exposure, removal of the thermoplastic polymer layer and the intermediate layer, development, removal of undeveloped residual parts, post-exposure and baking with an oven at 220° C. for 20 minutes were carried out in this order; and, in this way, a color filter substrate having a red sub-pixel pattern and a green sub-pixel patter thereon was produced.

Next, the photosensitive transfer material for forming blue sub-pixels, from which the cover film was removed, was laid on the glass substrate having the red sub-pixel pattern thereon, and, then, steps of removal of the temporary support, patterned exposure, removal of the thermoplastic polymer layer and the intermediate layer, development, removal of undeveloped residual parts, post-exposure and baking with an oven at 220° C. for 20 minutes were carried out in this order; and, in this way, a color filter substrate having a red sub-pixel pattern and a green sub-pixel patter and a blue sub-pixel pattern thereon was produced.

It is noted that, when each colored pattern was prepared, each photosensitive transfer material was laid on the surface of the glass substrate so that the flow direction with which each photosensitive polymer composition was applied to the surface of the substrate was parallel to the long direction (a horizontal direction of a liquid crystal panel) of the glass substrate.

Next, the photosensitive transfer material for forming black matrix, from which the cover film was removed, was laid on the glass substrate, having the red, green and blue sub-pixel patterns thereon, so that the surface of the photosensitive layer contacted the surface, on which the red, green and blue sub-pixel patterns were formed, of the substrate, and bonded to the surface of the substrate in the same manner described above. After that, the temporary support, polyethylene terephthalate film, was removed from other layers at an interface between the temporary support and the thermoplastic polymer layer. The photosensitive polymer layer was irradiated with light (irradiation energy: 70 mJ/cm²) by using an aligner (“MAP-1200L” manufactured by DAINIPPON SCREEN MFG. CO., LTD.) from the side of the surface, on which no colored layer was formed, of the substrate, and was subjected to a development treatment in the same manner as the red sub-pixel pattern and a post-exposure treatment at 240° C. for 50 minutes by using an oven to form a black image capable of blocking light (black matrix) on the portions where no red, green or blue images was formed.

In this way, a color filter comprising red, green and blue patterns and a black light-blocking pattern bridging gaps among the colored patterns was produced.

The retardation values of the red, green and blue sub-pixel patterns were measured, and the values were as follows:

Red sub-pixel: Re(629)=50 nm, Rth(629)=12 nm

Green sub-pixel: Re(548)=20 nm, Rth(548)=7 nm

Blue sub-pixel: Re(446)=4 nm, Rth(446)=38 nm

### —Method for Producing Liquid Crystal Cell—

Using the glass substrate having the color filter thereon as a lower substrate, a liquid crystal cell was produced by pouring liquid crystal material having a negative dielectric constant anisotropy (“MLC6608” manufactured by Merck) dropwise into a cell gap of 3.6 μm, and confining the material within the gap to form a liquid crystal layer. It was found that the value of Δn·d (d (μm): a thickness of the liquid crystal layer, Δn: birefringence of the liquid crystal material) was 300 nm. In the cell, liquid crystal was controlled to align vertically.

### —Method for Producing VA-mode Liquid Crystal Panel—

To a surface of the obtained VA-mode liquid crystal cell, polarizing plate HLC2-5618 manufactured by SANRITZ CORPORATION was adhered as an upper (observer side) polarizing plate; and to another surface, a polarizing plate, which was produced according to the method described in Japanese Patent Laid-Open Publication “Tokkai” No. 2006-8944, was adhered as a lower (backlight side) polarizing plate. In particular, a cellulose acylate was produced in the same manner as F-8 described in the publication, Example No. 1-1; and the lower polarizing plate was produced according to the method described in the publication, Example No. 2-1, 2-1-1. The lower polarizing plate was adhered to the liquid crystal cell so that the cellulose acylate film, F-8, was disposed at the liquid crystal cell side. The retardation values at three wavelengths of the cellulose acylate film, F-8, employed in the lower polarizing plate, were measured, and the values were as follows:

Re(446)=60 nm, Rth(446)=204 nm

Re(548)=54 nm, Rth(548)=200 nm

Re(629)=56 nm, Rth(629)=198 nm

Both of the upper and lower polarizing plates were adhered to the surfaces of the liquid crystal cell with an adhesive agent. The polarizing plates were disposed, in a crossed-Nicol arrangement, so that the transmission axis of the upper polarizing plate was aligned horizontally, and the transmission axis of the lower polarizing plate was vertically.

The liquid crystal was driven by applying with 55 Hz square-wave voltage, and was in the white state with 5V and in the black state with 0V, namely, normally black mode LCD.

The produced VA-mode LCD was observed in various directions such as a normal direction and oblique directions with various porlar angels and azimuthal angles, and, it was found that the LCD achieved neutral black states in any directions.

What is claimed is:

1. A color filter to be employed in a liquid crystal display device, comprising at least two colored sub-pixels in each pixel,
wherein at least one of the colored sub-pixels in each pixel comprises a retardation-controlling agent, and retardation is substantially different from each other between the two colored sub-pixels.

2. The color filter of claim 1, wherein at least one sub-pixel comprises a plurality of domains among which retardation is substantially different from each other.

3. A liquid crystal display device comprising a color filter as set forth in claim 1.

4. The liquid crystal display of claim 1, comprising a retardation plate disposed outside of a liquid crystal cell.

5. A photosensitive transfer material comprising a photosensitive polymer layer comprising at least, one retardation-controlling agent.

6. A process for producing a photosensitive transfer material comprising applying a photosensitive polymer composition comprising at least one retardation-controlling agent to a surface to form a photosensitive polymer layer

7. A process for producing a color filter to be employed in a liquid crystal display device comprising forming a photosensitive polymer layer comprising at least one retardation-controlling agent on a surface of a substrate.

8. A process for producing a color filter to be employed in a liquid crystal display device comprising:
forming a photosensitive polymer layer comprising at least one retardation-controlling agent on a surface of a substrate;
exposing the layer at least one time;
developing the layer at least one time; and
baking the layer at least one time.
